(19) United States
(12) Patent Application Publication
(10) Pub. No.: US 2025/0365876 A1
(43) Pub. Date: Nov. 27, 2025

(54) DEVICE AND METHOD FOR CONTROLLING VEHICLE

(71) Applicant: HYUNDAI MOBIS CO., LTD., Seoul (KR)

(72) Inventors: Shin Yeong Kim, Yongin-si (KR); Jae Min Kim, Yongin-si (KR)

(73) Assignee: HYUNDAI MOBIS CO., LTD., Seoul (KR)

(21) Appl. No.: 19/077,334

(22) Filed: Mar. 12, 2025

(30) Foreign Application Priority Data
May 27, 2024 (KR) 10-2024-0068450

(51) Int. Cl. H05K 5/02; B60K 35/53; G06F 3/14

(52) U.S. Cl. CPC H05K 5/0217; G06F 3/14; B60K 35/53

(57) ABSTRACT

A vehicle control device and method area disclosed. The vehicle control device includes a display device provided in a vehicle body, the display device includes a display configured to display visual information and a driving unit configured to change at least one of a shape of the display or a position of the display based on a mode, the vehicle body further includes a hidden button area covered by a part of the display, and the driving unit changes the position of the display to expose the hidden button area.

This application claims the benefit of Korean Patent Application No. 10-2024-0068450, filed on May 27, 2024, which is hereby incorporated by reference as if fully set forth herein.

### BACKGROUND

### Field

The present disclosure relates to a device and method for controlling a vehicle, and more specifically, to a vehicle control device and method for flexibly using a display in a vehicle.

### Discussion of the Related Art

Generally, various display devices capable of displaying images and visual information are installed and used in vehicles. One of these display devices may be installed around the driver's seat of a vehicle, for example, on the dashboard.

In this case, if the size of the display screen provided by the display device installed on the dashboard is large, there is an advantage in that a lot of diverse information can be delivered to the driver and/or passengers through a single display screen, but there is a disadvantage in that the possibility of interference between the display screen and other devices installed in the vehicle increases, which may obstruct the view of the driver and/or passengers.

On the other hand, if the size of the display screen is small, there is a disadvantage in that the amount of information that can be provided through a single display screen is reduced, but there is an advantage in that the possibility of interference between the display screen and other devices installed in the vehicle is low, which may reduce the possibility of obstructing the view of the driver and/or passengers.

### SUMMARY

The present disclosure is proposed to solve the above-mentioned problems and various problems related thereto, and an object of the present disclosure is to provide a vehicle control device and method capable of flexibly adjusting a display installed in a vehicle.

Another object of the present disclosure is to provide a vehicle control device and method capable of allowing a hidden area covered by a display to be used by changing the position of the display based on the purpose of the screen.

However, the scope of rights of the embodiments is not limited to the above-described objects and may be expanded to other objects that can be inferred by a person skilled in the art based on the entire contents of this document.

To achieve the above objects and other advantages, a device for controlling a vehicle includes a vehicle body, and a display device included in the vehicle body, wherein the display device includes a display configured to display visual information, and a driving unit configured to change at least one of a shape of the display or a position of the display based on a mode.

According to embodiments, the vehicle body may further include a hidden button area covered by a part of the display, the hidden button area may include at least one physical button for performing at least one function of the vehicle body, and the driving unit may change the position of the display to expose the hidden button area.

According to embodiments, the driving unit may change the shape of the display by folding or unfolding a part of the display at a predetermined angle based on the mode, and change the position of the display by sliding the display upward or downward.

According to embodiments, a display area of the display may be divided into a first area, a second area, and a third area arranged on a same surface, the second area may be located above the first area, the third area may be located below the first area, at least one of the second area or the third area may be folded or unfolded at a predetermined angle by the driving unit, and a folding angle of the second area and a folding angle of the third area may be the same or different.

According to embodiments, the mode may be divided into a first mode, a second mode, and a third mode, the second area and the third area may be in a folded state with respect to the first area in the first mode, the second area may be in a folded state and the third area may be in an unfolded state in the second mode, the second area and the third area may be in an unfolded state in the third mode, and the display may slide upward by a predetermined length in the third mode.

According to embodiments, the first area to the third area may operate as individual display screens in the first mode, the first area and the second area may operate as a single display screen in the second mode, and the first area to the third area may operate as a single display screen in the third mode.

According to embodiments, the second area may be turned off or display basic information in the first mode.

According to embodiments, the second area may be folded inward or outward in the first mode.

According to embodiments, the third area may display at least one virtual button for performing at least one function of the vehicle body in the first mode and the second mode.

According to embodiments, the third area may not display at least one virtual button for performing at least one function of the vehicle body in the third mode.

According to embodiments, the display device may be installed on a dashboard between a driver's seat and a passenger seat of the vehicle body.

According to embodiments, a method of controlling a vehicle includes changing at least one of a shape of a display of a display device provided in a vehicle body or a position of the display based on a mode, and exposing a hidden button area covered by a part of the display by changing the position of the display.

According to embodiments, the hidden button area may include at least one physical button for performing at least one function of the vehicle body.

According to embodiments, the shape of the display may be changed by folding or unfolding a part of the display at a predetermined angle based on the mode, and the position of the display may be changed by sliding the display upward or downward.

According to embodiments, a display area of the display may be divided into a first area, a second area, and a third area arranged on a same surface, the second area may be located above the first area, the third area may be located below the first area, at least one of the second area or the third area may be folded or unfolded at a predetermined angle, and a folding angle of the second area and a folding angle of the third area may be the same or different.

According to embodiments, the mode may be divided into a first mode, a second mode, and a third mode, the second area and the third area may be in a folded state with respect to the first area in the first mode, the second area may be in a folded state and the third area may be in an unfolded state in the second mode, the second area and the third area may be in an unfolded state in the third mode, and the display may slide upward by a predetermined length in the third mode.

According to embodiments, the first area to the third area may operate as individual display screens in the first mode, the first area and the second area may operate as a single display screen in the second mode, and the first area to the third area may operate as a single display screen in the third mode.

According to embodiments, the second area may be turned off or display basic information in the first mode.

According to embodiments, the second area may be folded inward or outward in the first mode.

According to embodiments, the third area may display at least one virtual button for performing at least one function of the vehicle body in the first mode and the second mode.

According to embodiments, the third area may not display at least one virtual button for performing at least one function of the vehicle body in the third mode.

According to embodiments, a computer program stored in a computer-readable recording medium may perform the above-described method by being combined with a computer as hardware.

The above-described solutions are only some of the various embodiments of the present disclosure, and those skilled in the art to which the present disclosure pertains can infer modified embodiments reflecting the technical features of the present disclosure through the overall intent described in the present disclosure.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram showing an example of a vehicle according to embodiments;

FIG. 2 is a diagram showing an example of the interior of the vehicle according to embodiments;

FIG. 3 is a block diagram showing an example of a display device according to embodiments;

FIG. 4 is a diagram showing an example of a display of the display device according to embodiments;

FIG. 5(a) to FIG. 5(c) are diagrams showing examples of shape changes and position changes of the display in a first mode to a third mode according to embodiments;

FIG. 6(a) and FIG. 6(b) are diagrams showing an example of a shape of the display in a vehicle and data displayed in each area in the first mode according to embodiments;

FIG. 7(a) and FIG. 7(b) are diagrams showing another example of a shape of the display in the vehicle and data displayed in each area in the first mode according to embodiments;

FIG. 8(a) and FIG. 8(b) are diagrams showing an example of a shape of the display in the vehicle and data displayed in each area in the second mode according to embodiments;

FIG. 9(a) and FIG. 9(b) are diagrams showing an example of a shape of the display in the vehicle and data displayed in each area in the third mode according to embodiments;

FIG. 10(a) and FIG. 10(b) are cross-sectional views showing an example of a state change of the display according to embodiments; and

FIG. 11(a) and FIG. 11(b) are cross-sectional views showing an example of a display folding/unfolding process according to embodiments.

### DETAILED DESCRIPTION

Hereinafter, embodiments disclosed in this specification will be described in detail with reference to the attached drawings. Regardless of the drawing symbols, the same or similar components will be given the same reference numerals and redundant descriptions thereof will be omitted. The following embodiments are intended only to concretize the present disclosure and do not limit or restrict the scope of the rights of the present disclosure. What those skilled in the technical field to which the present disclosure belongs can easily infer from the detailed description and embodiments of the present disclosure is interpreted as falling within the scope of the rights of the present disclosure.

The detailed description of the present disclosure should not be construed as restrictive in all respects, but should be considered exemplary. The scope of the present disclosure should be determined by a reasonable interpretation of the appended claims, and all changes within the equivalent scope of the present disclosure are included in the scope of the present disclosure.

The blocks of the attached block diagrams or the steps of the flowcharts may be implemented directly in hardware, implemented as software modules executed by hardware, or implemented by a combination thereof. In addition, the blocks of the attached block diagrams or the steps of the flowcharts may be interpreted as computer program instructions that are loaded into a processor or a memory of a device capable of data processing, such as a general-purpose computer, a special-purpose computer, a portable laptop computer, or a network computer, and perform designated functions. Since such computer program instructions may be stored in a memory included in a computer device or a computer-readable memory, the functions described in the blocks of the block diagrams or the steps of the flowcharts may be produced as a product that includes instruction means for performing the same.

In addition, each block or each step may represent a module, segment, or part of code that includes one or more executable instructions for executing a specific logical function(s). In addition, in some alternative embodiments, functions mentioned in blocks or steps may be executed in a different order from the specified order. For example, two blocks or steps depicted in succession may be performed substantially simultaneously, may be performed in reverse order, or may be performed with some blocks or steps omitted.

The present disclosure relates to a device and method for controlling a vehicle, and particularly, provides a display device having a foldable function and/or a sliding function. To this end, the display device of the present disclosure includes a flexible display. In the present disclosure, “display device” may be used interchangeably with “flexible display device”, and “display” may be used interchangeably with “flexible display”.

In the present disclosure, the display may perform only the foldable function or may perform the foldable function and the sliding function simultaneously based on the mode. In the present disclosure, the mode may be referred to as a driving mode or a display mode.

In the present disclosure, the foldable function means a function by which a part of the display can be folded and unfolded at a predetermined angle, and the sliding function means a function by which the display physically moves in a specific direction (e.g., up/down) to change the display position. In the present disclosure, a state in which a part of the display is folded at a predetermined angle is referred to as a folded state (or a folding state), and a state in which the display is unfolded is referred to as an unfolded state (or an unfolding state). That is, the present disclosure allows the shape (or form) of the display to be changed by the foldable function and allows the position of the display to be changed by the sliding function.

The present disclosure allows a hidden button area covered by a display to be used by changing the position of the display using the sliding function depending on the purpose of use. In the present disclosure, the hidden button area includes one or more physical buttons in an embodiment. The present disclosure can perform a specific function of a vehicle and/or a specific function of the display using one or more buttons of the hidden button area. In the present disclosure, “hidden button area” may be used interchangeably with “hidden area”.

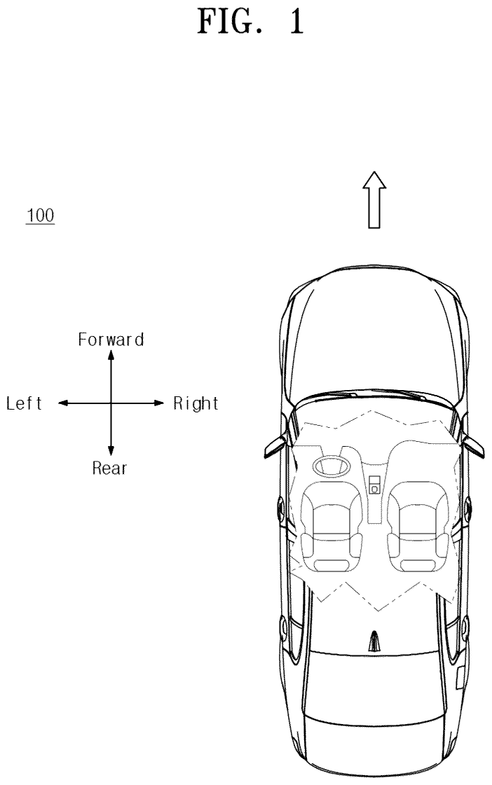

FIG. 1 is a diagram showing an example of a vehicle according to embodiments. In the present disclosure, for the convenience of description, a direction in which the vehicle 100 moves forward is referred to as a forward direction, and the left and right directions are distinguished based on the forward direction. When the forward direction is the 12 o'clock direction, the 3 o'clock direction or surroundings thereof are defined as the right direction, and the 9 o'clock direction or surroundings thereof are defined as the left direction. The opposite direction to the forward direction is the rear. In addition, the direction of the bottom of the vehicle 100 is referred to as a downward direction, and the opposite direction is referred to as an upward direction. Further, a side positioned in the forward direction is referred to as a front side, a side positioned in the back is referred to as a back side, and a side positioned on the side is referred to as a side. Among the sides, the side toward the left is defined as a left side, and the side toward the right is defined as a right side.

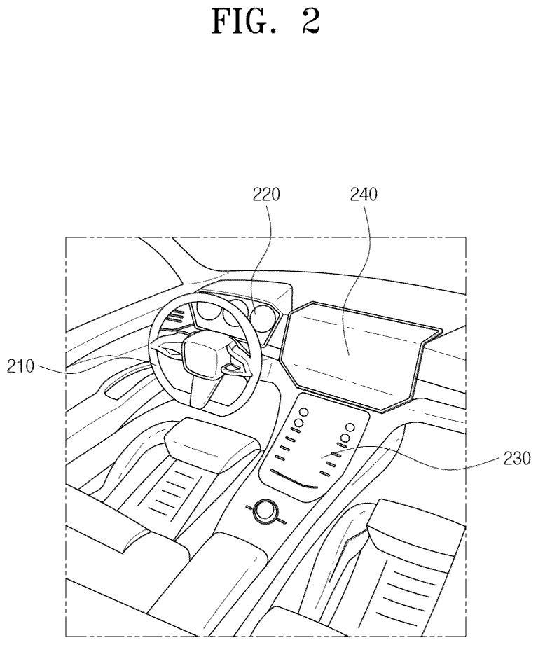

FIG. 2 is a diagram showing an example of the interior of a vehicle according to embodiments. In FIG. 2, there is a dashboard inside the vehicle that separates the driver's seat (and the passenger seat) from the engine compartment. The dashboard may be divided into a steering wheel 210, a cluster 220, a center fascia 230, a display device 240, and the like. The configuration of the vehicle interior and the dashboard shown in FIG. 2 is exemplary, and the configuration of the vehicle interior is not limited thereto.

In FIG. 2, the steering wheel 210 is configured to control the direction of the vehicle, and the cluster 220 displays information necessary for driving, including a speedometer.

The center fascia 230 is a panel board located between the driver's seat and the passenger seat in the center of the dashboard. Although not shown, a controller for controlling the vehicle, an air vent, a cup holder, and the like may be installed in the center fascia 230. When the dashboard is formed in a T shape, the center fascia 230 may serve as a wall separating the driver's seat from the passenger seat together with a center console for the driver to change gears and select a driving mode. In the present disclosure, the center fascia 230 is not flat. For example, the center fascia 230 may include a plurality of curved surfaces.

In the present disclosure, a plurality of display devices may be provided and may be installed at various locations. For example, the display devices may be installed on the dashboard, a rearview mirror, a rear seat, a windshield, a ceiling, and the like.

In the present disclosure, an example in which the display device 240 is installed (or mounted) on the dashboard will be described.

In the present disclosure, the display device 240 is positioned at the center of the dashboard, and in particular, as an example, at a position where the display device 240 meets vertically with the center fascia 230.

According to embodiments, the display in the display device 240 may include a plurality of display areas. In the present disclosure, an embodiment in which the display is divided into three display areas will be described. This is an example, and the number of display areas may be more or less than three. According to embodiments, the plurality of display areas may display independent images, or two or more areas may be combined to display one image.

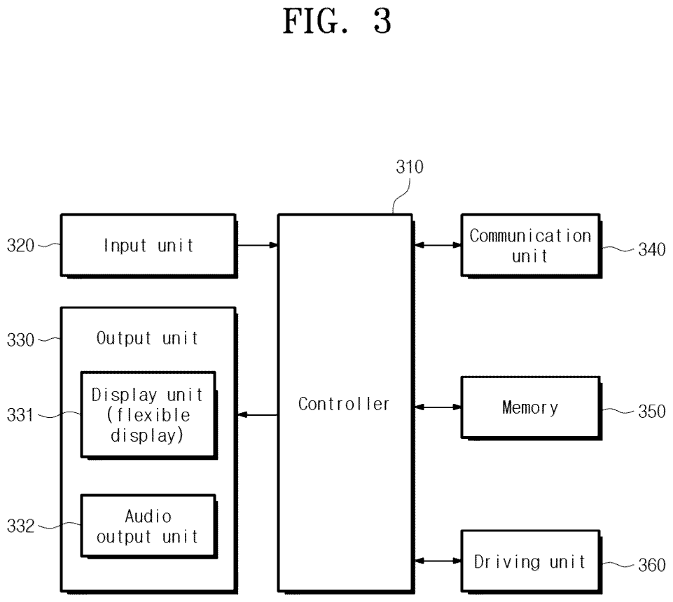

FIG. 3 is a block diagram showing an example of a display device according to embodiments. In FIG. 3, the display device may include a controller 310, an input unit 320, an output unit 330, a communication unit 340, a driving unit 350, and a memory 360. Each component in FIG. 3 corresponds to hardware, software, a processor, and/or a combination thereof. In addition, the execution order of the blocks in FIG. 3 may be changed, some blocks may be omitted, and some blocks may be newly added.

According to embodiments, the input unit 320 may receive operation commands for various functions that can be performed in the vehicle. In addition, the input unit 320 may receive commands for controlling the mode of the display from a user. In the present disclosure, the input unit 320 may include one or more cameras and/or sensors for inputting video signals, a microphone for inputting audio signals, and a user input unit (e.g., a touch key, a mechanical key, and the like) for receiving commands from the user. In addition, the input unit 320 may also receive information on a destination through text or voice when performing a navigation mode.

According to embodiments, the output unit 330 is provided to generate output related to vision, hearing, and the like, and can include a display unit 331 for displaying visual information and an audio output unit 332 for outputting auditory information.

According to embodiments, the display unit 331 includes a flexible display and may visually display information on a function being performed in the vehicle and information input by the user. According to embodiments, the flexible display may be implemented as at least one of a liquid crystal display (LCD), a thin film transistor-liquid crystal display (TFT-LCD), an organic light-emitting diode (OLED) display, a three-dimensional display (3D display), or an e-ink display. In the present disclosure, the display unit 331 may display information necessary to control various devices used for driving the vehicle and to drive the vehicle, information necessary to provide convenience to vehicle passengers, or display entertainment content. In the present disclosure, the entertainment content may be a still image, a moving image, a game, or the like. In the present disclosure, text, images, graphics, and the like displayed on the display will be referred to as visual information.

In the present disclosure, a detailed description of the display unit 331 will be given later.

According to embodiments, the audio output unit 332 includes a speaker, and may output all or some of information being displayed on the display unit 331 as sound or voice, or may output navigation information and the like as sound or voice. In addition, the audio output unit 332 may output audio of content being displayed on the display unit 331.

According to embodiments, the communication unit 340 may include one or more wireless communication modules that enable wireless communication between the display device 240 and a wireless communication system, between the display device 240 and another display device in the same vehicle, between the display device 240 and a display device of another vehicle, or between the display device 240 and an external server.

In the present disclosure, one or more wireless communication modules may support various wireless communication methods such as Wi-Fi, wireless broadband, global system for mobile communication (GSM), code division multiple access (CDMA), wideband code division multiple access (WCDMA), universal mobile telecommunications system (UMTS), time division multiple access (TDMA), long term evolution (LTE), 4G, 5G, and 6G. In addition, the communication unit 340 may include a short-range communication module. The short-range communication module may support short-range communication using at least one of Bluetooth, radio frequency identification (RFID), Infrared Data Association (IrDA), ultra-wideband (UWB), ZigBee, near field communication (NFC), Wireless-Fidelity (Wi-Fi), Wi-Fi Direct, or wireless Universal Serial Bus (USB). Such short-range communication modules may form short-range wireless communication networks (WLANs) such that short-range communication between the vehicle and at least one external device can be performed. For example, a mobile terminal of a user riding in the vehicle can be paired with the vehicle automatically or by execution of an application by the user.

According to embodiments, the communication unit 340 may further include a global positioning system (GPS) module. The GPS module may obtain the location of the vehicle using a signal transmitted from a GPS satellite, and the obtained location of the vehicle may be used for navigation.

According to embodiments, the communication unit 340 may receive a broadcast signal and/or broadcast-related information from an external broadcast management server through broadcast channels. The broadcast channels may include a satellite channel and/or a terrestrial channel. The broadcast signal may include not only a TV broadcast signal, a radio broadcast signal, and a data broadcast signal, but may also include a broadcast signal in the form of combination of a TV broadcast signal or a radio broadcast signal with a data broadcast signal. The broadcast-related information may mean information related to a broadcast channel, a broadcast program, or a broadcast service provider. The above-mentioned received broadcast signal and/or broadcast-related information may be provided to a user in the vehicle through the display unit 331 and/or the audio output unit 332 of the output unit 330 under the control of the controller 310 or may be stored in the memory 350.

According to embodiments, the memory 350 stores data supporting various functions of the display device 240. The memory 350 may store a plurality of application programs (or applications) executed in the display device 240, data for the operation of the display device 240, and instructions. At least some of such application programs may be downloaded from an external server via wireless communication of the communication unit 340. In addition, at least some of such application programs may be present on the display device 240 from the time of shipment for basic functions (e.g., call reception, call transmission, message reception, and call transmission) of the display device 240. Application programs may be stored in the memory 350, installed on the display device 240, and driven by the controller 310 to perform the operations (or functions) of the display device 240. In the present disclosure, the memory 350 may store map data for implementing a navigation function. Here, the map data may be stored as default when the vehicle is released. Alternatively, the map data may be received from an external device via the communication unit 340.

According to embodiments, the driving unit 360 may fold/unfold a part of the display included in the display unit 331 and/or slide the entire display up/down according to the control of the controller 310.

According to embodiments, the controller 310 may control the overall operation of each unit (e.g., the display device 240) in the vehicle in addition to operations related to the application programs. The controller 310 may provide appropriate information or functions to the user or process the same by processing signals, data, information, and the like input or output through the components describe above or by operating application programs stored in the memory 350. In addition, the controller 310 may control all or some of the components included in the display device 240 in order to operate application programs stored in the memory 360.

According to embodiments, the controller 310 may control the driving unit 360 to change the shape and/or position of the display included in the display unit 331. To this end, the driving unit 360 may include a motor, a hinge, and a gear.

In addition, the controller 310 may control the display unit 331 in order to flexibly use the display depending on the mode.

According to embodiments, the controller 310 may perform functions of an electronic control unit (ECU), functions of an advanced driver assistance system (ADAS), or the functions of both thereof. In the present disclosure, the controller 310 may be implemented in hardware using at least one of an application specific integrated circuit (ASIC), a digital signal processor (DSP), a digital signal processing device (DSPD), a programmable logic device (PLD), a field programmable gate array (FPGA), a processor, a controller, a microcontroller, a microprocessor, or other electrical units for performing functions.

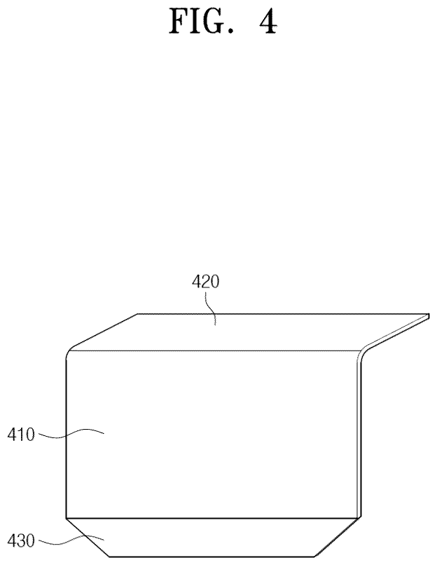

FIG. 4 is a diagram showing an example of a display of the display device according to embodiments. That is, the display device 240 may include the display unit 331, and the display unit 331 may include a flexible display.

According to embodiments, the display may include a plurality of display areas. In the present disclosure, an embodiment in which the display is divided into three display areas will be described. For convenience of description, the three display areas are referred to as a first area 410, a second area 420, and a third area 430 in the present disclosure.

In the present disclosure, the first area 410 is located between the second area 420 and the third area 430 and is a main area that always maintains a flat state in an embodiment. In addition, the second area 420 and the third area 430 may be referred to as sub-areas that are foldable, that is, can be folded or unfolded at a predetermined angle.

According to embodiments, the first area 410 to the third area 430 may each be formed by a touchscreen or may be formed by a single touchscreen.

In the present disclosure, the surface of the first area 410 where the touchscreen is visible may be the front, and the surface facing in the opposite direction to the front may be the back.

In the present disclosure, the first area 410 to the third area 430 are disposed on the front, and in particular, the second area 420 is positioned above the first area 410 and the third area is positioned below the first area 410 in an embodiment.

According to embodiments, the first area 410 to the third area 430 may have the same size or may have different sizes. In the present disclosure, it is assumed that the first area 410 is largest in an embodiment. The second area 420 and the third area 430 may have the same size or different sizes.

In the present disclosure, a state in which a part of the display is folded at a predetermined angle is referred to as a folded state, and a state in which the part of the display is unfolded is referred to as an unfolded state. In the present disclosure, the second area 420 and/or the third area 430 may be folded at a predetermined angle.

In the present disclosure, the unfolded state means a state in which the first area 410 and the second area 420 form an angle of 180 degrees (or about 180 degrees) or a state in which the first area 410 to the third area 430 all form an angle of 180 degrees (or about 180 degrees). In other words, the unfolded state means a state in which the first area 410 and the second area 420 are arranged substantially flat or a state in which the first area 410 to the third area 430 are arranged substantially flat.

In the present disclosure, the folded state means a state in which the second area 420 is folded at a predetermined angle and/or a state in which the third area 430 is folded at a predetermined angle with respect to the first area 410. Here, the angle at which the second area 420 is folded and the angle at which the third area 430 is folded may be the same or different.

In the present disclosure, the second area 420 may be folded inward or outward with respect to the first area 410. Here, the folding angle of the second area 420 may be fixed, or may be manually determined by the user or automatically determined by the controller 310. On the other hand, the third area 430 is folded only inward with respect to the first area 410 in an embodiment. Here, the folding angle of the third area 430 may be fixed, or may be manually determined by the user or may be automatically determined by the controller 310.

In the present disclosure, outward folding means a state in which the second area 420 is folded outward such that the touchscreen of the first area 410 and the touchscreen of the second area 420 face in opposite directions. Inward folding means a state in which the second area 420 is folded at a predetermined angle such that the touchscreen of the first area 410 and the touchscreen of the second area 420 face inward (i.e., the front), or a state in which the third area 430 is folded at a predetermined angle such that the touchscreen of the first area 410 and the touchscreen of the third area 430 face inward (i.e., the front).

According to embodiments, the display unit 331 may use the first area 410 to the third area 430 as independent screens or may combine at least two areas and use the combined area as one screen according to control of the controller 310 based on a mode. For example, the first area 410, the second area 420, and the third area 430 may be combined to form one large screen.

According to embodiments, the display unit 331 may include a plurality of modes.

In the present disclosure, it is assumed that a display off state is referred to as a default mode (or off mode) and a display on state is referred to as an operation mode.

In the present disclosure, the display off state corresponds to a case where the vehicle engine is not started or the vehicle engine is running but the display (or display device) is turned off. When the engine is running, the off mode may be selected by the user.

The operation mode is divided into three modes in an embodiment. In the present disclosure, the three modes are referred to as a first mode (or mode A), a second mode (or mode B), and a third mode (or mode C). The number of modes in the present disclosure is exemplary, and the present disclosure is not limited thereto.

In the present disclosure, the driving unit 360 may fold or unfold the second area 420 and/or the third area 430 at a predetermined angle depending on the mode. In addition, the driving unit 360 may slide the entire display in a vertical direction depending on the mode.

According to embodiments, the driving unit 360 may include a hinge that facilitates folding/unfolding of the second area 420 and/or the third area 430. In one embodiment, the hinge is disposed between the first area 410 and the second area 420 and between the first area 410 and the third area 430 to maintain a set shape or a folded angle of the second area 420 and/or the third area 430. That is, the first area 410 and the second area 420 may be connected by the hinge, and the first area 410 and the third area 430 may be connected by the hinge.

According to embodiments, in the default mode or in a state in which the second area 420 is off (i.e., nothing is displayed), the second area 420 may be folded inward (i.e., forward) or outward (i.e., rearward) relative to the first area 410 to secure a view for a user sitting in the driver's seat and/or passenger seat of the vehicle.

At this time, depending on the folding direction of the second area 420, i.e., whether the second area 420 is folded outward or inward, the display may be S-shaped or C-shaped in the default mode or in a state in which the second area 420 is off. In the present disclosure, folding outward is referred to as out-folding, and folding inward is referred to as in-folding.

In the present disclosure, the second area 420 is folded inward with respect to the first area 410 when the second area 420 is on (e.g., when an image, text, or graphic is displayed) in an embodiment.

In the present disclosure, the second area 420 is in a folded state in the first mode and in an unfolded state in the second and third modes in an embodiment.

In the present disclosure, the third area 430 is in a folded state in the first mode and the second mode, and in an unfolded state in the third mode in an embodiment.

In summary, both the second area 420 and the third area 430 are in a folded state in the first mode, the second area 420 is in an unfolded state and the third area 430 is in a folded state in the second mode, and both the second area 420 and the third area 430 are in an unfolded state in the third mode. In other words, in the present disclosure, the shape of the display varies depending on the mode in an embodiment.

According to embodiments, when the second area 420 is in a folded state, nothing may be displayed in the second area 420 (e.g., a black screen or a screen in the same color as the dashboard) or basic information, such as a welcome message, artificial intelligence (AI) communication, weather, current time, emergency information, an interior image, etc. may be displayed. The basic information listed here is an example, and since the basic information in the present disclosure may be added, changed, or deleted, it is not limited to the information listed above.

According to embodiments, when the third area 430 is in a folded state, one or more virtual buttons for performing specific functions may be displayed in the third area 430. Here, each virtual button may be in the form of an icon or a graphic shape by which the relevant function can be recognized. Alternatively, the virtual buttons may be grouped in relation to a specific function. At this time, the third area 430 may include one or more pages depending on the number of virtual buttons, the arrangement of the virtual buttons, etc. In this case, the user can go to the next page by selecting an arrow or an icon indicating the next page.

For example, when the third area 430 is in a folded state, the third area 430 may include an air conditioning control area related to an air conditioner, a heater, and the like, and one or more virtual buttons for performing functions related to air conditioning may be arranged in the air conditioning control area. For example, the user may touch one or more buttons in the air conditioning control area to control the air direction, air volume, temperature, etc. In another embodiment, a car control button and a volume adjustment button may be further displayed in the third area 430.

As another example, when the third area 430 is in an unfolded state, that is, in the third mode (i.e., an entertainment mode), a vehicle full option control button for entertainment may be displayed in the third area 430.

In the present disclosure, the number of virtual buttons displayed in the third area 430, functions, and arrangement locations of the virtual buttons may be changed, and addition and deletion may also be possible.

According to embodiments, the first area 410 to the third area 430 operate individually in the first mode. That is, navigation information and main content may be displayed in the first area 410, basic information may be displayed in the second area 420 in a folded state, and one or more virtual buttons for vehicle control and air conditioning may be displayed in the third area 430 in a folded state. As another example, in the first mode, nothing may be displayed in the first area 410.

According to embodiments, in the second mode, when the second area 420 is unfolded, the first area 410 and the second rea 420 are combined into one display area. The combined display area may operate independently from the third area 430. That is, one image, for example, navigation information or main content, is expanded and displayed in the combined display area, and one or more virtual buttons for car control, air conditioning, and the like are displayed in the third area 430 in a folded state. In another embodiment, in the second mode, when the second area 420 is unfolded, the first area 410 and the second area 420 are arranged in a flat state, but the first area 410 and the second area 420 may operate independently. In other words, the first area 410 to the third area 430 may operate independently. In this case, navigation information, main content, or the like may be displayed in the first area 410, and basic information may be displayed in the second area 420.

According to embodiments, in the third mode, the second area 420 and the third area 430 are unfolded and simultaneously the display slides upward. In this case, the first area 410 to the third area 430 are combined into one display area. Then, entertainment content is displayed in the combined display area. In the present disclosure, the entertainment content may be a still image, a moving image, a TV program, a game, etc. At this time, buttons for controlling entertainment may be displayed in the third area 430. In the present disclosure, the third mode in which the first area 410 to the third area 430 are combined to form one large screen and entertainment content is displayed through this large screen may be referred to as an entertainment mode.

Further, when the display including the first area 410 to the third area 430 slides upward in the third mode, the area covered by the third area 430 is exposed. This area is referred to as a hidden button area in the present disclosure.

In the present disclosure, the hidden button area includes one or more physical buttons in an embodiment. In the present disclosure, at least one physical button may be a dial type or a touch type.

In the present disclosure, at least one physical button of the hidden button area is a button capable of performing the function of at least one virtual button among the virtual buttons displayed in the third area 430 in the first mode and the second mode in an embodiment. For example, at least one button of the hidden button area may serve as virtual buttons of the air conditioning control area displayed in the third area 430 in the first mode and the second mode. That is, some or all of the virtual buttons displayed in the third area 430 in the first mode or the second mode may disappear from the third area 430 for display of entertainment content in the third mode, and in this case, at least one button in the hidden button area may be used to perform the functions of the virtual buttons.

In the present disclosure, some of the physical buttons in the hidden button area may be buttons for new functions unrelated to the functions of one or more virtual buttons displayed in the third area 430 in the first mode or the second mode.

In the present disclosure, the first mode, the second mode, and the third mode may be manually selected by the user, or may be automatically selected by the controller 310 depending on the state of the vehicle.

For example, the controller 310 may select the first mode when the display is in an off mode, and may select the first mode or the second mode when the vehicle is in a normal driving mode. In addition, the controller 310 may select the third mode in a parking, stopping, or autonomous driving mode.

As described above, in the present disclosure, the third mode is referred to as the entertainment mode, and the shape and position of the display are changed by sliding the display including the first area 410 to the third area 430 upward while unfolding the second area 420 and the third area 430 during parking, autonomous driving, or stopping. That is, when the second area 420 and the third area 430 are unfolded, the display area is expanded to the full size (i.e., one large screen), and the display slides upward and thus the hidden button area appears for the entertainment mode.

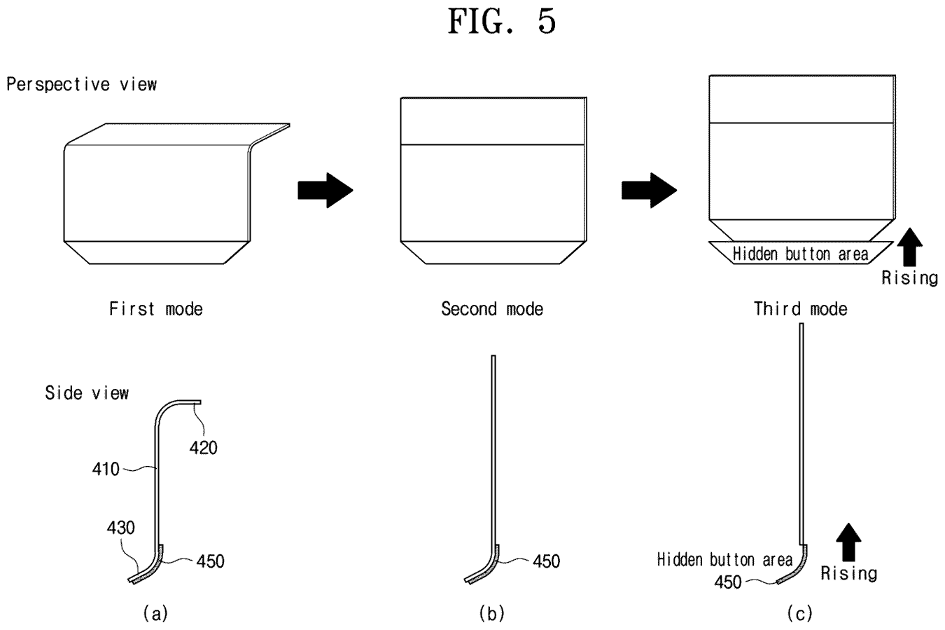

FIG. 5(a) to FIG. 5(c) are diagrams showing examples of changes in the shape (or form) and position of the display according to the first to third modes. In order to avoid redundant descriptions, some descriptions may be omitted in FIG. 5(a) to FIG. 5(c). Therefore, refer to the descriptions of FIG. 2 to FIG. 4 for the descriptions omitted in FIG. 5(a) to FIG. 5(c).

In FIG. 5(a) to FIG. 5(c), the upper part is examples of a perspective view of the first area 410 to the third area 430 of the display whose shape changes depending on the mode, and the lower part is examples of a side view of the first area 410 to the third area 430 of the display whose shape changes depending on the mode.

More specifically, FIG. 5(a) is an example in the first mode, in which the second area 420 and the third area 430 are both in a folded state with respect to the first area 410, and the hidden button area 450 is covered by the third area 430. That is, since the third area 430 covers the hidden button area 450, users riding in the driver's seat and/or the passenger seat of the vehicle cannot see the hidden button area 450 due to the third area 430. At this time, the angle at which the second area 420 is folded and the angle at which the third area 430 is folded may be the same or different.

FIG. 5(b) is an example in the second mode, in which the second area 420 is in an unfolded state and the third area 430 is in a folded state with respect to the first area 410, and the hidden button area 450 is covered by the third area 430. That is, in the second mode, the third area 430 also covers the hidden button area 450, and thus users riding in the driver's seat and/or the passenger seat of the vehicle cannot see the hidden button area 450 due to the third area 430. At this time, the first area 410 and the second area 420 may be arranged substantially flat to form one display area (i.e., display screen) or may form separate display areas.

FIG. 5(c) is an example in the third mode, in which the second area 420 and the third area 430 are both unfolded with respect to the first area 410 and the display including the first area 410 to the third area 430 has slid upward. At this time, the sliding distance may be fixed to a predetermined value or may be selected by a user. That is, when the display rises upward through sliding, the hidden button area 450 covered by the third area 430 is exposed. In other words, users riding in the driver's seat and/or the passenger seat of the vehicle can see the hidden button area 450 that was covered by the third area 430. At this time, the first area 410 to the third area 430 are substantially all arranged flat to form one display area (i.e., display screen). That is, a large screen is formed in the third mode.

Only the shape (or form) of the display is changed in the first and second modes of the present disclosure, whereas both the shape and position of the display are changed in the third mode.

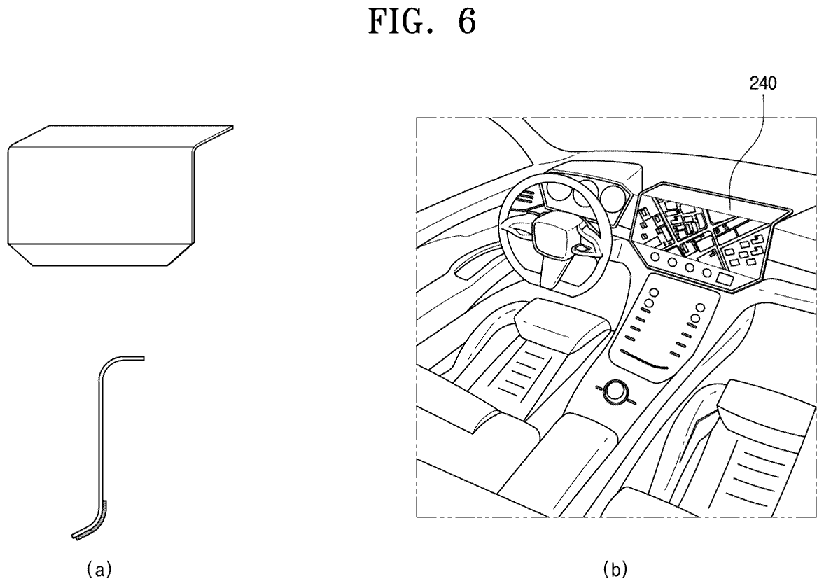

FIG. 6 to FIG. 9 are diagrams showing examples of changes in the shape (or form) and position of the display according to the first to third modes within the vehicle. That is, (a) in FIG. 6 to FIG. 9 corresponds to FIG. 5(a) to FIG. 5(c), and (b) in FIG. 6 to FIG. 9 shows an actual state of the display according to each mode in the vehicle.

According to embodiments, in the first mode, nothing may be displayed in the second area 420 or basic information may be displayed therein. In the present disclosure, the basic information may include a welcome message, AI communication, emergency information, weather, current time, an interior image, etc.

According to embodiments, in the second mode, the second area 420 may display basic information or may be combined with the first area 410 to form one display area, and a portion of an image displayed in the first area 410 may be displayed therein.

More specifically, FIG. 6(a) shows a state in the first mode and corresponds to FIG. 5(a), and FIG. 6(b) is an example of the display displayed in the vehicle in the first mode. FIG. 6(b) shows a case where nothing is displayed in the second area 420. That is, FIG. 6(a) and FIG. 6(b) correspond to the first mode and show an example when the screen of the second area 420 is turned off in the off mode and the normal driving mode. In this case, navigation information or main content is displayed in the first area 410, and one or more virtual buttons are displayed in the third area 430. In addition, when the second area 420 is unnecessary, for example, in the off mode in which the screen of the second area 420 is turned off, the second area 420 may be hidden to secure a front view. For example, the second area 420 may be folded outward by more than 90 degrees with respect to the first area 410 such that the user riding in the vehicle cannot see the second area 420.

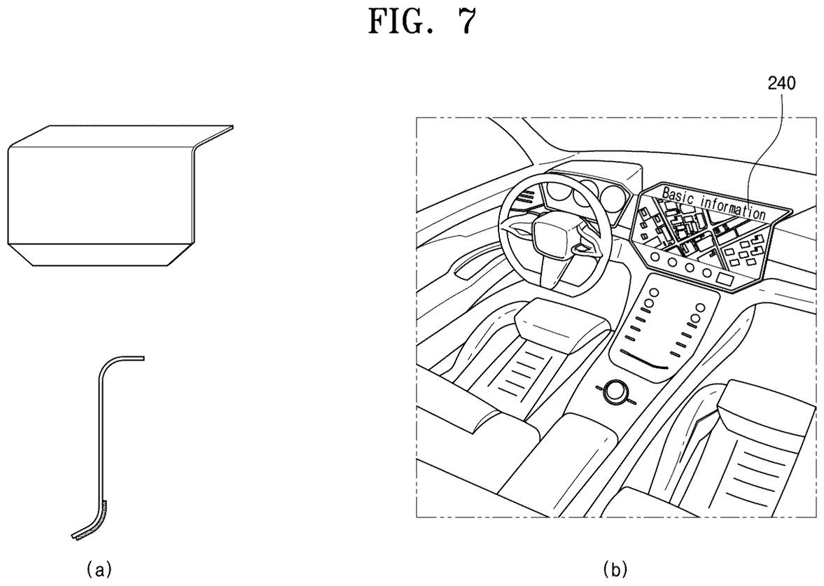

FIG. 7(a) shows a state in the first mode and corresponds to FIG. 5(a), and FIG. 7(b) is another example of the display displayed in the vehicle in the first mode. FIG. 7(b) shows a case where basic information is displayed in the second area 420. In this case, navigation information or main content is displayed in the first area 410, basic information is displayed in the second area 420, and one or more virtual buttons are displayed in the third area 430. At this time, the second area 420 is folded inward.

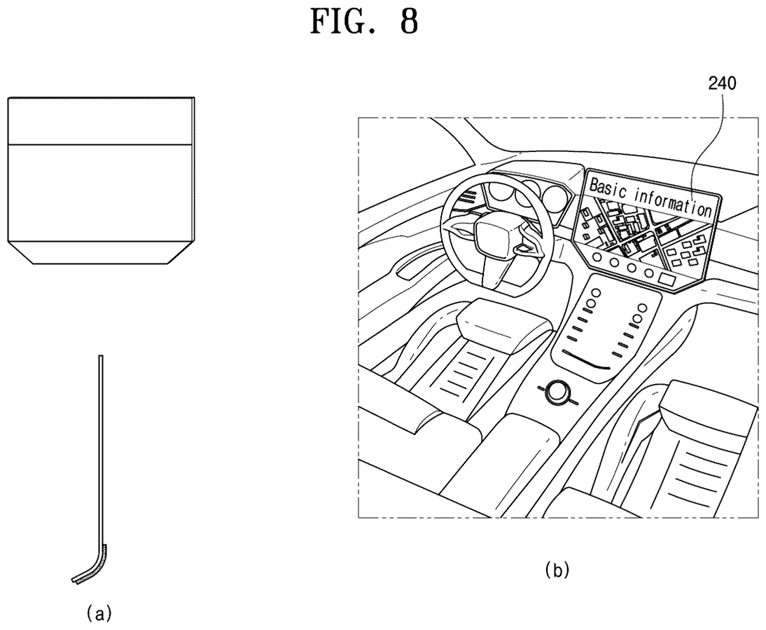

FIG. 8(a) shows a state in the second mode and corresponds to FIG. 5(b), and FIG. 8(b) is an example of the display displayed in the vehicle in the second mode. FIG. 8(b) shows a case where the image of the first area 410 is expanded and also displayed in the second area 420. In this case, the first area 410 and the second area 420 are arranged flat and thus the first area 410 and the second area 420 are combined to operate as a single display screen. In another example, the first area 410 and the second area 420 are arranged flat, but the first area 410 and the second area 420 may operate individually. In this case, navigation information or main content is displayed in the first area 410, basic information is displayed in the second area 420, and one or more virtual buttons are displayed in the third area 430.

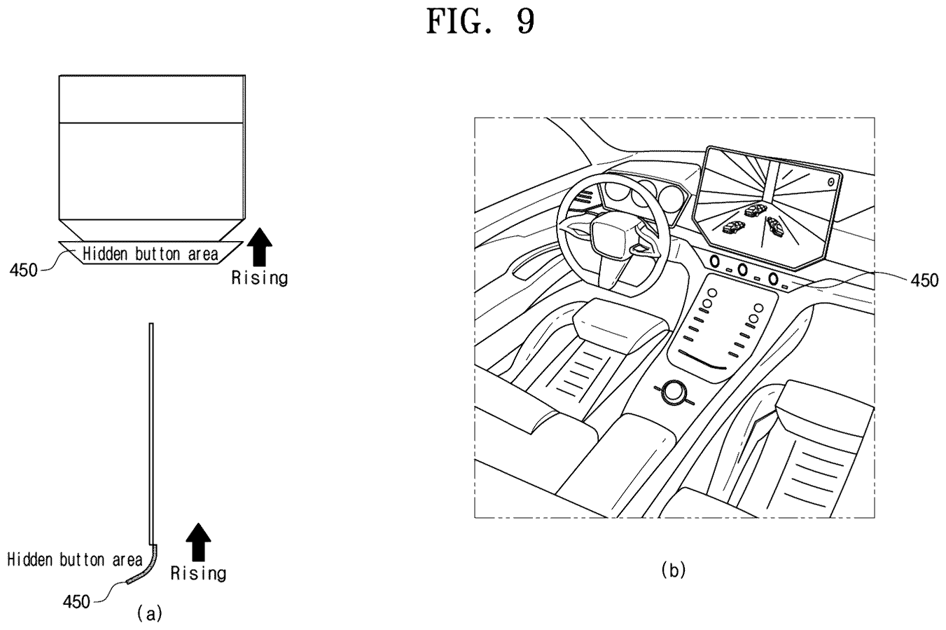

FIG. 9(a) shows a state in the third mode and corresponds to FIG. 5(c), and FIG. 9(b) is an example of the display displayed in the vehicle in the third mode. In the third mode, the second area 420 and the third area 430 are unfolded, the first area 410 to the third area 430 are all arranged flat, and the first area 410 to the third area 430 are combined to operate as a single large screen. That is, entertainment content is displayed on the large screen. In addition, in the third mode, the display including the first area 410 to the third area 430 slides upward (or rises), and thus the hidden button area 450 that was covered when the third area 430 was unfolded is exposed.

In the present disclosure, the hidden button area 450 may include one or more physical buttons. Here, each physical button may be a dial-type or a touch-type. In addition, at least one physical button of the hidden button area 450 may perform the function of at least one virtual button among the virtual buttons displayed in the third area 430 in the first mode and the second mode. For example, at least one button of the hidden button area 450 may serve as the virtual buttons for the air conditioning control area displayed in the third area 430 in the first mode and the second mode. That is, some or all of the one or more virtual buttons displayed in the third area 430 in the first mode and the second mode may disappear from the third area 430 in order to display entertainment content in the third mode, and in this case, at least one button of the hidden button area 450 may be used to perform the functions thereof. In the present disclosure, some of the physical buttons in the hidden button area may be buttons for new functions unrelated to the functions of the one or more virtual buttons displayed in the third area 430 in the first mode or the second mode.

In the present disclosure, disappearance of a virtual button displayed in the third area 430 in the first and second modes in the third mode means that the function performed by touching the virtual button in the third area 430 in the first and second modes cannot be performed in the third mode. In other words, the present disclosure can perform a specific function by switching from a virtual button to a physical button or by switching from a physical button to a virtual button depending on the mode.

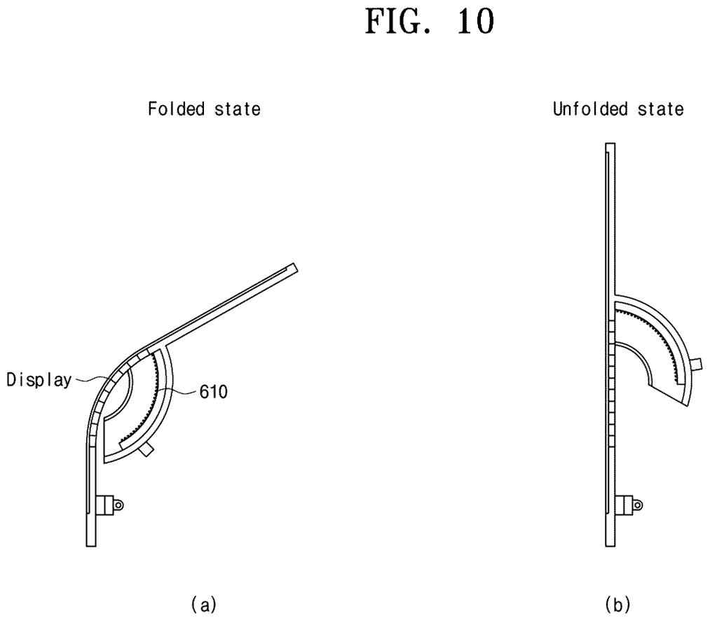

FIG. 10(a) and FIG. 10(b) are cross-sectional views showing examples of changes in the state of the display according to embodiments. That is, FIG. 10(a) is an example of the second area 420 of the display in a folded state, and FIG. 10(b) is an example of the second area 420 of the display in an unfolded state.

In FIG. 10(a) and FIG. 10(b), the reference numeral 610 indicates an inscribed curved rack gear, which is disposed between the first area 410 and the second area 420 to support the first area 410 and the second area 420 such that they are inscribed and rotate with each other. In addition, the inscribed curved rack gear is disposed between the first area 410 and the third area 430 to support the first area 410 and the third area 430 such that they are inscribed and rotate with each other. That is, the inscribed curved rack gear can fold or unfold the second area 420 and/or the third area 430 at a desired angle.

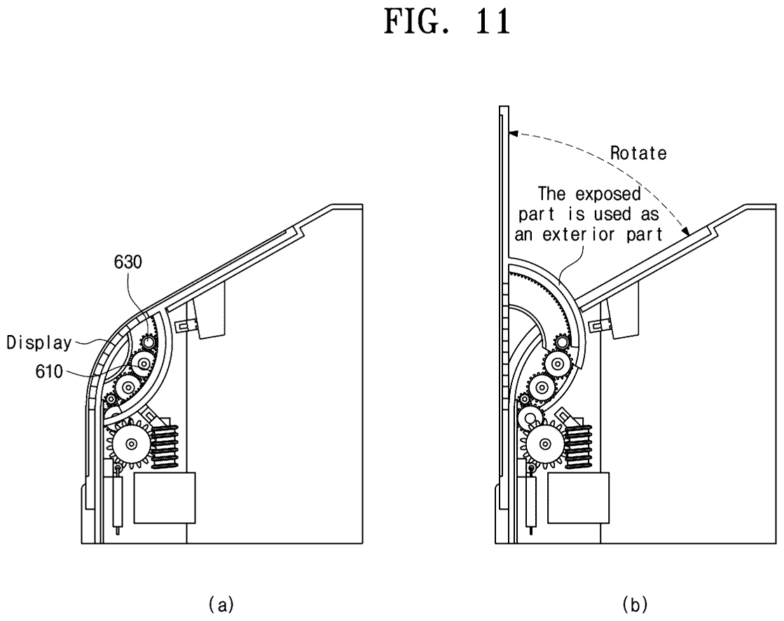

FIG. 11(a) and FIG. 11(b) are cross-sectional views showing examples of display folding/unfolding processes according to embodiments.

According to embodiments, the driving unit 360 may fold/unfold the second area 420 and the third area 430 and/or slide the display including the first area 410 to the third area 430 based on the control of the controller 310. FIG. 11(a) and FIG. 11(b) show examples in which the second area 420 is folded and unfolded.

According to embodiments, the driving unit 360 may include the curved rack gear 610 and a pinion gear 630. In the present disclosure, the pinion gear 630 engages with the curved rack gear 610 and may be rotated by a motor. In the present disclosure, the curved rack gear 610 is attached to a hinge connecting two display areas (e.g., the first area 410 and the second area 420), and the hinge operates together with the curved rack gear 610 to enable folding and unfolding of the second area 420. That is, the curved rack gear 610 has teeth formed on a surface facing the pinion gear 630 to engage with the pinion gear 630, and may move in a specific direction according to the rotation of the pinion gear 630 to fold or unfold the display area (e.g., the second area 420). Here, the specific direction may be a direction for folding the second area 420 as in FIG. 11(a) or a direction for unfolding the second area 420 as in FIG. 11(b). In other words, in the folding process, the motor rotates the pinion gear 630 to move the curved rack gear 610, which folds the second area 420 through the hinge. In the unfolding process, the motor rotates the pinion gear 630 in the opposite direction to move the curved rack gear 610, which unfolds the second area 420 through the hinge.

As described above, according to the present disclosure, the shape and/or position of the display are changed depending on the mode, and the type of data displayed in each display area of the display changes. In the present disclosure, the first mode to the third mode and the first area 410 to the third area 430 have been described as an embodiment. In the present disclosure, the number and definition of modes, the number and definition of areas, and the like may be changed through addition, deletion, or modification, and the changed part is also included in the present disclosure.

In the present disclosure, selection of a mode may be automatically determined by the controller 310 according to the state of the vehicle (e.g., driving, stopping, parking, refueling, or the like), or may be directly determined by a user riding in the vehicle.

In the present disclosure, the second area 420 and the third area 430 are in a folded state in the first mode, and the second area 420 is in a folded state and the third area 430 is in an unfolded state and in the second mode. In the third mode, the second area 420 and the third area 430 are in an unfolded state, and the display including the first area 410 to the third area 430 rises upward through sliding.

In the present disclosure, folding/unfolding of the second area 420 and/or the third area 430 and sliding of the display including the first area 410 to the third area 430 are performed by the driving unit 360 under the control of the controller 310 in an embodiment. Further, data (e.g., images, text, graphic, etc.) displayed in the first area 410 to the third area 430 are displayed by the display unit 331 under the control of the controller 310 in an embodiment.

In the first mode, the first area 410 may display navigation information, main content, etc., the second area 420 may be in an off state or may display basic information, and the third area 430 may display virtual buttons (e.g., buttons for volume control, air conditioning control, etc.) for performing some functions in the vehicle by touch.

In the second mode, the first area 410 and the second area 420 may be arranged flat to form a single screen. In this case, navigation information, main content, etc. displayed in the first area 410 are extended to the second area 420 and displayed. At this time, virtual buttons (e.g., buttons for volume control, air conditioning control, etc.) for performing some functions in the vehicle are displayed in the third area 430. As another example, in the second mode, the first area 410 may display navigation information, main content, etc., and the second area 420 may display basic information.

In the third mode, the first area 410 to the third area 420 may be arranged flat to form a single screen (i.e., a large screen). In this case, the third mode becomes an entertainment mode, and entertainment content is displayed in the first area 410 to the third area 430. In the present disclosure, the entertainment content may be a still image, a moving image, a TV program, a game, etc. At this time, the virtual buttons displayed on the third area 430 disappear. As another example, virtual buttons for controlling the vehicle disappear, and only virtual buttons for controlling the entertainment content displayed on the first area 410 to the third area 430 remain or may be newly added.

However, in the case of the third mode in the present disclosure, the second area 420 and the third area 430 are unfolded, and simultaneously the display including the first area 410 to the third area 430 slides upward and rises, thereby exposing the hidden button area that was covered by the third area 430.

In the present disclosure, the hidden button area may include one or more physical buttons, and at least one of the physical buttons may be a button for performing all or some of the functions performed by the virtual buttons of the third area 430 in the first mode or the second mode. For example, at least one button of the hidden button area may serve as the virtual buttons related to the air conditioning control area displayed in the third area 430 in the first mode or the second mode. That is, some or all of one or more virtual buttons displayed in the third area 430 in the first mode or the second mode may disappear from the third area 430 in order to display entertainment content in the third mode, and in this case, at least one button in the hidden button area may be used to perform the functions thereof. In the present disclosure, some of the physical buttons in the hidden button area may be buttons for new functions unrelated to the functions of one or more virtual buttons displayed in the third area 430 in the first mode or the second mode.

The above-described parts, modules, or units may be software, processors, or hardware parts that execute consecutive execution processes stored in a memory (or storage unit). Steps described in the above-described embodiments may be performed by processors, software, or hardware parts. Each of the modules/blocks/units described in the above-described embodiments may operate as a processor, software, or hardware. In addition, the methods presented in the embodiments may be executed as code. The code may be written in a processor-readable storage medium, and thus may be read by a processor provided by an apparatus.

Although this specification has been described separately for the convenience of explanation, it is also possible to design new embodiments by combining the embodiments described in figures. In addition, designing a computer-readable recording medium in which a program for executing the previously described embodiments is recorded according to the needs of a person skilled in the art is also within the scope of the present disclosure.

The device and method according to the present disclosure are not limited to the configuration and method of the embodiments described above, but the embodiments may be configured by selectively combining all or some of the embodiments such that various modifications can be made.

In this disclosure, terms such as “first” and “second” may be used to describe various components of the disclosure. However, the various components according to the disclosure should not be limited in their interpretation by the above terms. These terms are merely used to distinguish one component from another. For example, a first user input signal may be referred to as a second user input signal. Similarly, the second user input signal may be referred to as the first user input signal. The use of these terms should be construed as not departing from the scope of the various embodiments. Although the first user input signal and the second user input signal are both user input signals, they do not mean the same user input signals unless the context clearly indicates otherwise.

The terms used to describe the disclosure are used for the purpose of describing particular embodiments and are not intended to limit the embodiments. As used in the description of the embodiments and in the claims, the singular is intended to include the plural unless the context clearly indicates otherwise. In addition, the expression “and/or” is used to include all possible combinations of terms. The expression “include” describes the presence of features, numbers, steps, elements, and/or components, and does not imply the exclusion of additional features, numbers, steps, elements, and/or components. Conditional expressions such as “if” and “when” used to describe the present disclosure are not intended to be limited to only optional cases. When a specific condition is satisfied, a related operation is performed in response to the specific condition, or a related definition is intended to be interpreted.

The vehicle control device and method according to the embodiments can increase the usability of a display by changing the shape or position of the display based on the mode.

The vehicle control device and method according to the embodiments can provide convenience to a user by appropriately adjusting the size of a display area depending on the mode.

The vehicle control device and method according to the embodiments can conveniently change the size of a displayed screen by folding or unfolding a part of the display depending on the purpose of use, and can save space. That is, it is possible to fold a part of the display so as not to obstruct the view of the driver and/or passengers or unfold the entire display to achieve a large-screen display depending on the purpose of use.

The vehicle control device and method according to the embodiments have the advantage of being able to perform some of vehicle control functions that are not displayed on the screen due to switching to the entertainment mode using buttons in a hidden area covered by a part of the display by sliding the display upward such that the hidden area is exposed depending on the mode.

In addition to the technical effects explicitly mentioned above, effects that are obvious to those skilled in the art can also be inferred through the entire description of this specification.

Therefore, the above detailed description is to be construed in all aspects as illustrative and not restrictive. The scope of the disclosure should be determined by the appended claims and their legal equivalents, not by the above description, and all changes coming within the meaning and equivalency range of the appended claims are intended to be embraced therein.

What is claimed is:

1. A device for controlling a vehicle, comprising:
a vehicle body; and
a display device included in the vehicle body,
wherein the display device comprises:
a display configured to display visual information; and
a driving unit configured to change at least one of a shape of the display or a position of the display based on a mode,
wherein the vehicle body further includes a hidden button area covered by a part of the display,
wherein the hidden button area includes at least one physical button configured to perform at least one function of the vehicle body, and
wherein the driving unit changes the position of the display to expose the hidden button area.

2. The device of claim 1, wherein the driving unit changes the shape of the display by folding or unfolding a part of the display at a predetermined angle based on the mode, and changes the position of the display by sliding the display upward or downward.

3. The device of claim 2, wherein a display area of the display is divided into a first area, a second area, and a third area arranged on a same surface, the second area is located above the first area, the third area is located below the first area, at least one of the second area or the third area is folded or unfolded at a predetermined angle by the driving unit, and a folding angle of the second area and a folding angle of the third area are the same or different.

4. The device of claim 3, wherein the mode is divided into a first mode, a second mode, and a third mode, the second area and the third area are in a folded state with respect to the first area in the first mode, the second area is in a folded state and the third area is in an unfolded state in the second mode, the second area and the third area are in an unfolded state in the third mode, and the display slides upward by a predetermined length in the third mode.

5. The device of claim 4, wherein the first area to the third area operate as independent display screens in the first mode, the first area and the second area operate as a single display screen in the second mode, and the first area to the third area operate as a single display screen in the third mode.

6. The device of claim 5, wherein the second area is turned off or displays basic information in the first mode.

7. The device of claim 5, wherein the second area is folded inward or outward in the first mode.

8. The device of claim 5, wherein the third area displays at least one virtual button for performing at least one function of the vehicle body in the first mode and the second mode.

9. The device of claim 8, wherein the third area does not display at least one virtual button for performing at least one function of the vehicle body in the third mode.

10. The device of claim 5, wherein the display device is installed on a dashboard between a driver's seat and a passenger's seat of the vehicle body.

11. A method of controlling a vehicle, comprising:
changing at least one of a shape of a display of a display device provided in a vehicle body or a position of the display based on a mode by a driving unit; and
exposing a hidden button area covered by a part of the display by changing the position of the display using the driving unit,
wherein the hidden button area includes at least one physical button configured to perform at least one function of the vehicle body.

12. The method of claim 11, wherein the shape of the display is changed by folding or unfolding a part of the display at a predetermined angle based on the mode, and the position of the display is changed by sliding the display upward or downward using the driving unit.

13. The method of claim 12, wherein a display area of the display is divided into a first area, a second area, and a third area arranged on a same surface, the second area is located above the first area, the third area is located below the first area, at least one of the second area or the third area is folded or unfolded at a predetermined angle, and a folding angle of the second area and a folding angle of the third area are the same or different.

14. The method of claim 13, wherein the mode is divided into a first mode, a second mode, and a third mode, the second area and the third area are in a folded state with respect to the first area in the first mode, the second area is in a folded state and the third area is in an unfolded state in the second mode, the second area and the third area are in an unfolded state in the third mode, and the display slides upward by a predetermined length in the third mode.

15. The method of claim 14, wherein the first area to the third area operate as independent display screens in the first mode, the first area and the second area operate as a single display screen in the second mode, and the first area to the third area operate as a single display screen in the third mode.

16. The method of claim 15, wherein the second area is turned off or displays basic information in the first mode.

17. The method of claim 15, wherein the second area is folded inward or outward in the first mode.

18. The method of claim 15, wherein the third area displays at least one virtual button for performing at least one function of the vehicle body in the first mode and the second mode.

19. The method of claim 18, wherein the third area does not display at least one virtual button for performing at least one function of the vehicle body in the third mode.

20. A computer program stored in a computer-readable recording medium, wherein the program is configured to execute the method of claim 11 when executed by a computer combined with hardware.
